(19) United States
(12) Patent Application Publication
(10) Pub. No.: US 2005/0253256 A1
(43) Pub. Date: Nov. 17, 2005

(54) Supply line arrangement, off chip driver arrangement, and semiconductor circuitry module

(76) Inventor: Aaron John Nygren, Muenchen (DE)

Correspondence Address: SLATER & MATSIL LLP, 17950 PRESTON ROAD, SUITE 1000, DALLAS, TX, 75252, US

(21) Appl. No.: 10/835,389

(22) Filed: Apr. 30, 2004

(51) Int. Cl. H03K 19/0175

(52) U.S. Cl. 257/724

(57) ABSTRACT

A supply line arrangement is provided wherein cutting means are provided which are adapted in order to subdivide and electrically insulate subsets or groups of provided off chip drivers with respect to each other wherein said cutting means are provided within internal first and second supply lines for internally supplying power or signals to the plurality of off chip drivers.

### FIELD OF THE INVENTION

The present invention relates to a supply line arrangement, to an off chip driver arrangement, as well as to a semiconductor circuitry module.

### BACKGROUND OF THE INVENTION

For providing and communicating internally derived and generated signals semiconductor circuitry modules are provided with an arrangement of so-called off chip drivers. These off chip drivers receive said internally derived and/or generated signals and supply them through a given package arrangement and via so-called chip pads to so-called package pins. The individual drivers or off chip drivers of the off chip driver arrangement have to be energized in order to enable a proper action by said off chip drivers. Therefore a supply line arrangement comprising a plurality of internal supply lines is provided. Said internal supply lines provide respective voltage and current to respective supply terminals of the off chip drivers.

However, in prior art supply line arrangements said first and said second internal supply lines are common supply lines for a plurality or for the entirety of the given off chip drivers. Therefore, noise problems might occur which reflect the dependence of the supplied voltage or current from the number of off chip drivers to be driven and from the signals which have to be driven by the respective off chip drivers.

### OBJECT OF THE INVENTION

It is therefore an object of the present invention to provide a supply line arrangement, an off chip driver arrangement, as well as a semiconductor circuitry module wherein the above-mentioned noise problem on the supply lines can be reduced or avoided.

### SUMMARY OF THE INVENTION

To solve the above-mentioned problem the present invention provides a supply line arrangement according to independent claim 1. Additionally, the present invention provides an off chip driver arrangement according to independent claim 7. Additionally, the present invention provides a semiconductor circuitry module according to claim 8. Preferred embodiments of the inventive supply line arrangement are within the scope of the dependent subclaims.

According to the present invention and according to a first best mode for carrying out the same the inventive supply line arrangement is adapted for internally supplying power or signals to a plurality of off chip drivers. The inventive supply line arrangement comprises at least a pair of first and second internal supply lines, wherein said first and said second internal supply lines are adapted in order to be internally connected to first and second supply terminals of off chip drivers. Additionally, cutting means are provided within or in said internal first and second supply lines, wherein said cutting means are adapted in order to subdivide and electrical insulate groups or subsets of said plurality of off chip drivers with respect to each other.

It is therefore a key aspect of the present invention to provide cutting means in or within said internal first and second supply lines. By insulating or cutting said first and second internal supply lines in order to subdivide and electrically insulate groups of the said plurality of off chip drivers an interaction of the different current paths and therefore a feedback of the process of providing current to a first group of drivers to the process of providing current to another and different group of drivers or even to the process of generating and providing signals to the package pins are reduced or even avoided.

According to a preferred embodiment of the present invention and according to a further best mode for carrying out the same pairs of adjacent off chip drivers are used as said groups of off chip drivers. Additionally or alternatively, said first and said second internal supply lines are externally connected or connectable to first and second external supply lines for providing respective power or signals from external.

According to a further preferred and advantageous embodiment of the present invention and according to a further best mode for carrying out the same first and second supply points are provided in order to establish said respective connection between said first and said second internal supply lines and said first and said second external supply lines.

According to a further preferred embodiment of the present invention and according to a further best mode for carrying out the same simple cuts or disconnections may be used as cutting means. Thereby, the common principle of providing common first and second internal supply lines which are common for each of the entirety of the off chip drivers is left.

Alternatively, pairs of complementary diodes which are provided anti-parallely in or within said first and second internal supply lines may be used as said cutting means.

Additionally or alternatively, switches, transistors and/or capacitors may be used as cutting means.

According to a further aspect of the present invention an off chip driver arrangement for a semiconductor circuitry module is provided which comprises a plurality of off chip drivers and a supply line arrangement according to the present invention as described above in order to internally supply power and/or signals to said off chip drivers.

It is a further aspect of the present invention to provide a semiconductor circuitry module which comprises an off chip driver arrangement according to the present invention as described above.

These and further aspects will become more clear taking reference to the following remarks:

This invention inter alia solves the noise problem associated with connecting multiple off chip drivers (OCDs) to dedicated supply lines.

Noise is introduced on the supply lines when current is sourced or sank through the package inductors. The voltage drop/spikes on the supplies is related to the equation dv=L di/dt, where L is the package inductance, di/dt is the rate of change of the current through the inductor, and dv is the resulting change in supply voltage. A pattern dependent noise arises as more or less OCDs drive at the same time (called Simultaneous Switching Noise (SSO)). If one OCD drives a signal for one period, and maximum all OCDs drive the next period, or any combinations where different amounts of OCDs drive from period to period, the supply network will see different amounts of current and voltage drop from period to period. This in turn causes timing errors between the different signals.

In most integrated circuits, all OCDs are connected to one dedicated set off supply nets; call them VDDQ for power and VSSQ for gnd. The supply net is connected through a package and inductance via a multiple of supply pins. There might be one OCD per supply pin, but more often there are two or more OCDs per supply pin. More important is that all pins connect to a common supply network, and in turn, all OCDs share this network. Herein lies the problem. As an example, assume that 16 OCDs share a supply network connected off-chip via eight VDDQ and eight VSSQ pins. On average, each set of supply pins supplies current to two OCDs. However, in an extreme case, eight sets of supply pins supply current to one OCD. This leads to a factor of 16 difference in available supply current from best to worse case, assuming the supply line distribution is ideal.

This invention inter alia alleviates the problem by isolating the supply nets to a certain number of OCDs. Taking the previous example, one could cut the supply line between the 16 OCDs so that only eight OCDs connect to four sets of supply lines. This leads to a best/worst case supply current factor of eight. This splitting can be repeated to a desired point to the best case of one set of supplies for two OCDs, leading to a ratio of two in this example. Of course, this ratio can be improved if more supplies exist.

The splitting of supply lines, however, cannot be done without further considerations. Electro Static Discharge (ESD) protection will be compromised if the lines are simply cut. Several alternatives exist to correct the issue. One alternative is to use complementary diodes to connect the cut nets. During an ESD event, the diodes will short-circuit, allowing for and ESD path to the entire VDDQ or VSSQ network. Another alternative is to connect the networks in the package, outside of the chip. However, this solution is not so optimal because some of the distributed package inductance will not be isolated as desired.

A key idea is the isolation of the supply lines to a subset or group of OCDs, and in particular the connection of the supply net via diodes.

FIG. 3 shows the prior art configuration. Shown here are eight OCDs all sharing a common supply network on the chip. The two extreme cases would be, for example, if the left most driver drives a “1”, and all others a “0”. In this case, the leftmost driver will pull current through the VDDQ not via the 4 shown package pins, plus any other that may exist further along in either direction (not shown here). The other OCDs will share the VSSQ net, meaning that 7 OCDs will share 4 pins. This means that the voltage drop seen on the VSSQ net because of the package inductance will be a factor 7 greater.

FIG. 1 shows the version proposed by this invention. The white squares shown on the chip-side supply lines represent the “cutting” of the supply. In the shown example, crosscoupled diodes are used to dynamically connect the nets in the case of the ESD event. Now in this example, again if the leftmost OCD drives a “1” and all other a “0”, the worst case difference in current (therefore voltage drop) will be a factor of 2.

### SHORT DESCRIPTION OF THE FIGURES

FIG. 1 is a schematical block diagram describing a first embodiment of the inventive supply line arrangement and of the inventive off chip driver arrangement comprising the latter.

FIG. 2 is a schematical block diagram describing a preferred embodiment for the cutting means.

FIG. 3 is a schematical block diagram of a prior art supply line arrangement and a prior art off chip driver arrangement.

### DETAILLED DESCRIPTION OF PREFERRED EMBODIMENTS

In the following similar or equivalent structures and elements will be denoted by the same reference symbols. Not in each case of their occurrence a detailed description will be repeated.

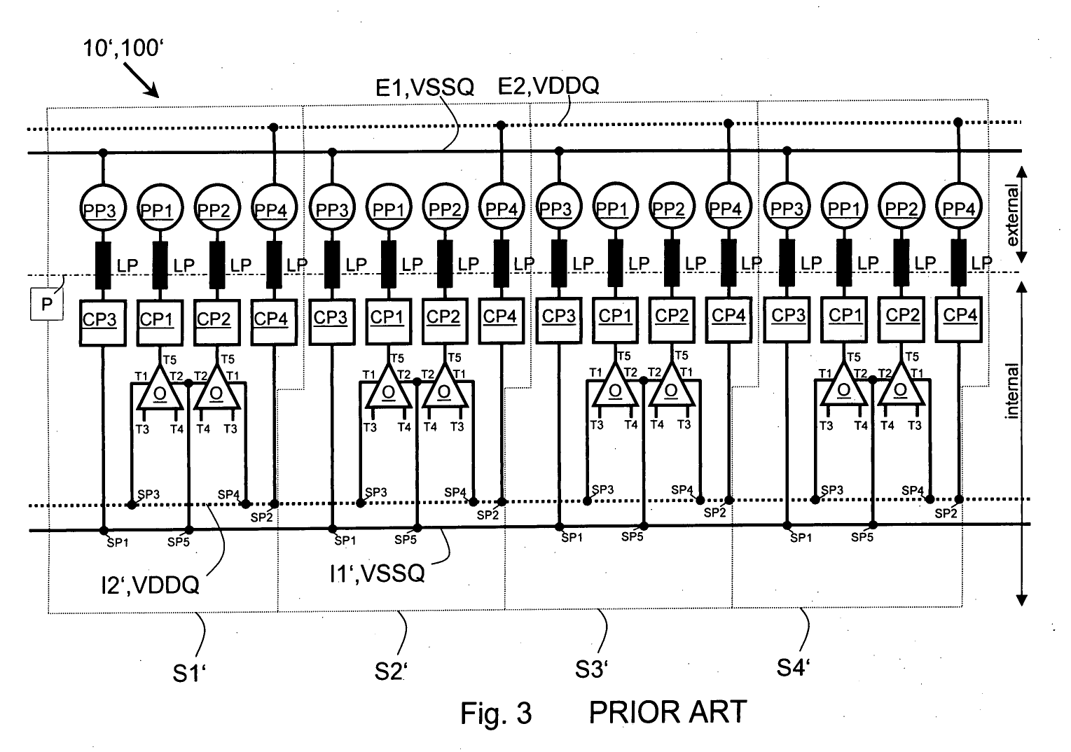

Before describing preferred embodiments of the present invention reference is taken to FIG. 3 showing by means of a schematical block diagram a prior art supply line arrangement 10′ as well as a prior art off chip driver arrangement 100′ of a prior art semiconductor circuitry module.

In FIG. 3 there is distinguished an external portion E and an internal portion I of a common semiconductor circuitry module. The separation of the internal portion I from the external portion E is given by a package P which is indicated by dashed lines. Within the internal portion I there is provided an arrangement 100′ of off chip drivers O pairs of which are arranged as groups S1′, S2′, S3′, S4′. Of course, there might be more than four groups.

Each off chip driver O comprises first and second power supply terminals T1 and T2, additionally signal terminals T3, T4 and T5 are provided for each of said off chip drivers O in order to receive input signals and in order to output a generated output signal, respectively. The output signal is output via terminal T5 to a so-called chip pad CP1, CP2. The output signal is supplied through the package P to an external package pin PP1, PP2, respectively. LP indicates an inductance which is generated by the wiring between the chip pads CPj and the package pins PPj as well as by the package P itself.

The power supply terminals T1 and T2 are connected to supply points SP3, SP4 and SP5, respectively, and thereby with provided first and second internal supply lines I1, 12, respectively.

First internal supply line I1 may supply a first voltage VDDQ and second internal supply line 12 may supply a second voltage VSSQ. Said first voltage VDDQ is received from external via supply point SP1 and respective chip pads CP3, package pins PP3 through which a electric connection to a respective first external supply line E1 is realized. Equivalently, through a first supply point SP2 a connection between said second internal supply line 12 and a respective second external supply line E2 is established via a respective chip pad CP4 and a respective package pin PP4 in order to receive said second voltage VSSQ from external.

As can be seen from the prior art embodiment shown in FIG. 3 said first and second internal supply lines 11 und 12 are common connecting supply lines for all of the off chip drivers O of the off chip driver arrangement 100′ as there is no electrically insulating subdivision of the groups S1′ to S4′.

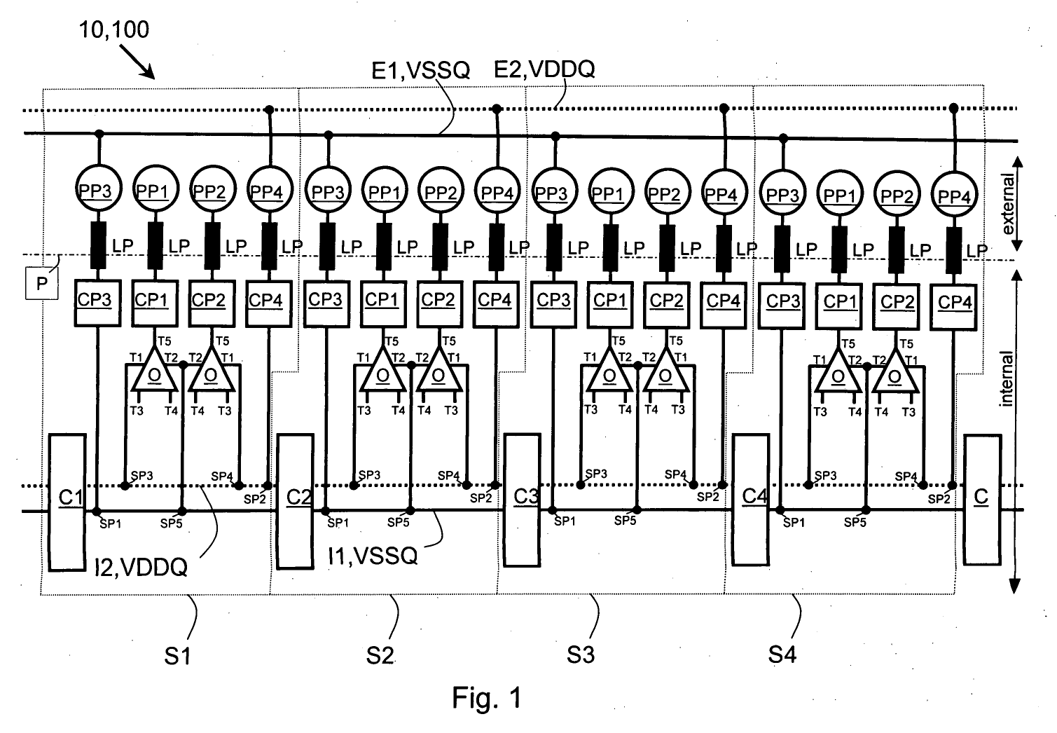

In contrast thereto the embodiment according to the present invention shown in FIG. 1 is with respect to some basic elements very similar to the prior art embodiment as shown in FIG. 3 except for the inventive provision of the cutting means C1 to C4 which are arranged and provided in order to electrically insulate and therefore electrically disconnect the formerly common internal supply lines 11 and 12 between adjacent pairs of off chip drivers O and to thereby electrically insulate the respective off chip drivers O. Therefore, the internal supply lines 11 and 12 are realized in a quasi-local manner in order to avoid an interaction between the supply line sections associated with the different groups S1 to S4 of pairs of off chip drivers O.

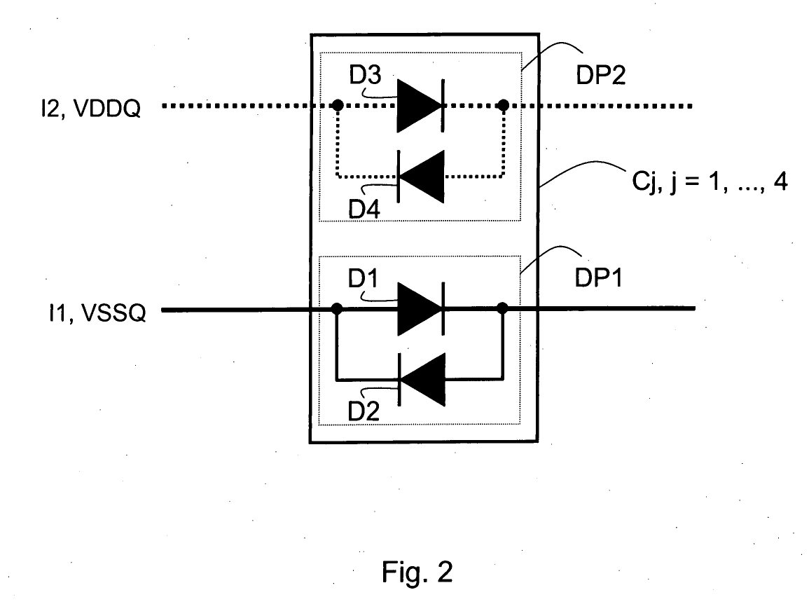

FIG. 2 is a schematical block diagram demonstrating an embodiment for the cutting means C1 to C4. Therefore the cutting means is generally denoted by Cj with j=1, . . . , 4.

Each cutting means Cj comprises a first and a second pair DP1, DP2 of first and second diodes D1, D3 and D2, D4, respectively. Each of said first and second diodes D1, D3 and D2, D4 are arranged and connected anti-parallely within said first and second internal supply lines 11 and 12 and therefore built complementary diodes.

### REFERENCE SYMBOLS

10 supply line arrangement according to the present invention
10′ prior art supply line arrangement
100 off-chip driver arrangement according to the present invention
100′ prior art off-chip driver arrangement
C1 cutting means
C2 cutting means
C3 cutting means
C4 cutting means
CP1 chip pad
CP2 chip pad
CP3 chip pad
CP4 chip Pad
D1 diode
D2 diode
D3 diode
D4 diode
DP1 pair of diodes
DP2 pair of diodes
E1 first external supply line
E2 second external supply line
I1 first internal supply line
I2 second internal supply line
LP package inductance
O off-chip driver
P package
PP1 package pin
PP2 package pin
PP3 package pin
PP4 package pin
S1 first group
S2 second group
S3 third group
S4 fourth group
S1′ first group
S2′ second group
S3′ third group
S4′ fourth group
SP1 first supply point
SP2 second supply point
SP3 third supply point
SP4 fourth supply point
SP5 fifth supply point
T1 first supply terminal
T2 second supply terminal
T3 third supply terminal
T4 fourth supply terminal
T5 fifth supply terminal

1. Supply line arrangement, which is adapted for internally supplying power or signals to a plurality of off chip drivers:
comprising at least a pair of first and second internal supply lines,
wherein said first and second internal supply lines are adapted to be internally connected to first and second supply terminals of off chip drivers, and
comprising cutting means in or within said internal first and second supply lines,
wherein said cutting means are adapted in order to subdivide and electrically insulate groups of said plurality of off chip drivers with respect to each other.

2. Supply line arrangement according to claim 1, wherein said groups of off chip drivers are pairs of adjacent off chip drivers.

3. Supply line arrangement according to claim 1, wherein said first and said second internal supply lines are externally connected or connectable to respective first and second external supply lines for externally providing respective power or signals.

4. Supply line arrangement according to claim 3, further comprising first and second supply points in order to establish said respective connection between said first and second internal supply lines and said first and second external supply lines.

5. Supply line arrangement according to claim 2, wherein simple cuts are provided as cutting means.

6. Supply line arrangement according to claim 5, wherein said cutting means is one of the group which comprises pairs of complementary diodes, switches, transistors and capacitors.

7. Off chip driver arrangement for a semiconductor circuit module, comprising a plurality of off chip drivers and a supply line arrangement according to claim 1 for internally supplying power and/or signals to said off chip drivers.

8. Semiconductor circuitry module, comprising an off chip driver arrangement according to claim 7.
